(19) United States
(12) Patent Application Publication
(10) Pub. No.: US 2022/0165590 A1
(43) Pub. Date: May 26, 2022

(54) DIE PICKUP DEVICE AND METHOD

(71) Applicant: SJ Semiconductor(Jiangyin) Corporation, Jiangyin City (CN)

(72) Inventors: Chunying ZHANG, Jiangyin City (CN); Xingtao XUE, Jiangyin City (CN); Chengchung LIN, Jiangyin City (CN)

(21) Appl. No.: 17/533,699

(22) Filed: Nov. 23, 2021

(30) Foreign Application Priority Data
Nov. 23, 2020 (CN) 202022726826X
Nov. 23, 2020 (CN) 2020113217267

(51) Int. Cl. H01L 21/67; H01L 21/683

(52) U.S. Cl. CPC H01L 21/67144; H01L 21/6838

(57) ABSTRACT

The present invention provides a die pickup device and method. The die pickup device comprises: a carrier table, comprising a horizontal table surface configured to place dies; a pushing element arranged in the carrier table, which includes an ejector pin switchable between an extended state and a retracted state in a direction vertical to the horizontal table surface, wherein when the ejector pin is in the extended state, the top of the ejector pin is higher than the horizontal table surface and can be kept fixed at a plurality of height positions; and a vacuum fixture configured to clamp the dies from the carrier table which is arranged above the carrier table. In the present invention, a die pickup device and process of large-scale chips are optimized and adjusted, thereby ensuring that the process of picking up dies of large-scale chips have a higher success rate; and through a multiple height lifting ejector pin design and adjusting the lifting height and retention duration of the ejector pin, the vacuum fixture can successfully pick up large-scale chip dies.

### CROSS REFERENCE TO RELATED APPLICATION

The present application claims the benefit of priority to Chinese Patent Application No. CN 202011321726.7, entitled “DIE PICKUP DEVICE AND METHOD”, and Chinese Patent Application No. CN 202022726826.X, entitled “DIE PICKUP DEVICE”, both filed with CNIPA on Nov. 23, 2020, the disclosure of both applications is incorporated herein by reference in its entirety.

### FIELD OF TECHNOLOGY

The present invention relates to the technical field of semiconductor packaging, in particular to a die pickup device and method.

### BACKGROUND

With the development of information technology, requirements for performance and integration levels of semiconductor chips have been increasing. In fields like automotive chips, large-scale chips are now widely used and show good future potentials.

Currently, in the packaging process of large-scale chips, the success rate of chip die pickup is one of the most important factors affecting the packaging yield and cost. If abnormalities such as dropping or shifting occur during the die pickup, the dies cannot be packaged normally in different packaging sites, and the dies may even be broken and scrapped.

However, for the large-scale chip dies, their dimension and quality both exceed what the specifications of the existing normal-sized chip dies require, thus, it is even more difficult to ensure the success rate of picking up these large-scale chip dies by using the existing die pickup devices and processes. If the success rate of die pick up is too low, abnormalities such as dropping or shifting during die pick up will arise, which will further affect the product yield of large-scale chips.

Therefore, it is urgent that a new die pickup device and method be developed to solve the above problems.

### SUMMARY

The present invention provides a die pickup device and method for achieving large-scale chips picking up successfully in packing process.

The die pickup device according to the present invention including:

a carrier table, including a horizontal table surface above a pushing element, wherein the horizontal table surface is configured to place the die;

ejector pins configured to mount on the horizontal table surface, wherein the ejector pins are configured to switch between an extended state and a retracted state in a direction perpendicular to the horizontal table surface, wherein when the ejector pins are in the extended state, each of the ejector pins is configured to be at a same height as other ejector pins in the extended state, wherein a top of each of the ejector pins is higher than the horizontal table surface, and is able to stay locked at different height positions; and

a vacuum fixture configured to grab the die from the horizontal table surface of the carrier table.

As an optional solution of the present invention, the different height positions of the ejector pins able to be locked at comprises at least a first height and a second height; wherein the second height is greater than the first height, and wherein the difference between the first height and the second height is smaller than the first height.

As an optional solution of the present invention, the pushing element further includes a drive unit configured to drive the ejector pins to extend or retract in a direction perpendicular to the horizontal table surface.

As an optional solution of the present invention, the pushing element further includes a timing unit configured to control the duration for which the ejector pins remaining locked at the first height and the second height.

As an optional solution of the present invention, the die is rectangular, having an area greater than 25×25 mm², wherein an upper surface of the pushing element is exposed out of the horizontal table surface of the carrier table, wherein the upper surface of the pushing element is a circular table surface with a diameter greater than 45 mm.

As an optional solution of the present invention, the ejector pins are distributed in a concentric array on the circular table surface of the pushing element, and wherein a distance from each of outermost ejector pins in the concentric array to a closet edge of the circular table surface is one third of a radius of the circular table surface.

As an optional solution of the present invention, a number of the ejector pins is five, wherein one of the ejector pins is arranged in a center of the circular table surface, and remaining four of the ejector pins are evenly place around the center at a same distance from the ejector pin at the center.

As an optional solution of the present invention, the vacuum fixture includes a vacuum nozzle and a structure arranged around the vacuum nozzle; wherein a size of the structure is greater than 20×20 mm².

As an optional solution of the present invention, the die pickup device further includes:

a control unit which connects to the pushing element and the vacuum fixture, wherein the control unit is configured to control the pushing element to push the die, to control the vacuum fixture to pick up the die, and to determine whether the vacuum fixture has picked up the die.

The present invention further provides a die pickup method, including the following steps:

1) providing the die pickup device stated in the present invention;

2) placing the die to be picked up on the carrier table;

3) pushing the die to the first height through the ejector pins and locking the ejector pins at the first height for a first retention duration;

4) pushing the die to the second height through the ejector pins and locking the ejector pins at the second height for a second retention duration, wherein the second height is greater than the first height; and

5) picking up the die through the vacuum fixture.

As an optional solution of the present invention, the first retention duration and the second retention duration are both 0.05 to 1 second.

As an optional solution of the present invention, the method further includes following steps after step 5):

step 6) determining whether the vacuum fixture has picked up the die;

step 7) when confirming that the vacuum fixture has picked up the die, grabbing and transferring the die with the vacuum fixture; and when determining that the vacuum fixture has not picked up the die, returning the ejector pins to the retracted state and performing step 3) to step 7) again.

As described above, the present invention provides a die pickup device and method. By optimizing and adjusting the die pickup device and operating process of large-scale chips, the process of picking up dies of large-scale chips can have a high success rate. Through the multiple height lifting ejector pin design and the ejector pin's lifting height and retention duration adjustment, the vacuum fixture can successfully pick up those large-scale chip dies.

### BRIEF DESCRIPTION OF THE DRAWINGS

FIG. 1 shows a partial schematic diagram of a die pickup device provided in embodiment 1 of the present invention.

FIG. 2 shows a schematic diagram of a front view of a pushing element provided in embodiment 1 of the present invention.

FIG. 3 shows a schematic diagram of a top view of the pushing element provided in embodiment 1 of the present invention.

FIG. 4 shows a schematic diagram of a front view of a vacuum fixture provided in embodiment 1 of the present invention.

FIG. 5 shows a schematic diagram of a bottom view of the vacuum fixture provided in embodiment 1 of the present invention.

FIG. 6 shows a flow chart of a die pickup method provided in embodiment 2 of the present invention.

FIG. 7 shows a schematic diagram of placing a die to be picked up on a carrier table as provided in embodiment 2 of the present invention.

FIG. 8 shows a schematic diagram of pushing the die to the first height by means of ejector pins as provided in embodiment 2 of the present invention.

FIG. 9 shows a schematic diagram of pushing the die to the second height by means of the ejector pins as provided in embodiment 2 of the present invention.

FIG. 10 shows a schematic diagram of picking up the die by a vacuum fixture as provided in embodiment 2 of the present invention.

FIG. 11 shows a schematic diagram of the die being picked up by the vacuum fixture as provided in embodiment 2 of the present invention.

### REFERENCE NUMERALS

| | |
|---|---|
| 101 | carrier table |
| 101a | horizontal table surface |
| 102 | pushing element |
| 102a | ejector pins |
| 102b | rod structure |
| 103 | vacuum fixture |
| 103a | vacuum nozzle |
| 103b | fixed structure |
| 200 | die |
| S1-S5 | steps 1) to 5) |

### DETAILED DESCRIPTION

The implementation of the present invention will be illustrated below through particular specific examples, and those skilled in the art can easily understand other advantages and effects of the present invention from the content disclosed in the present specification. The present invention can also be implemented or applied through other different specific implementations, and various details in the present specification can also be modified or changed based on different viewpoints and applications without departing from the spirit of the present invention.

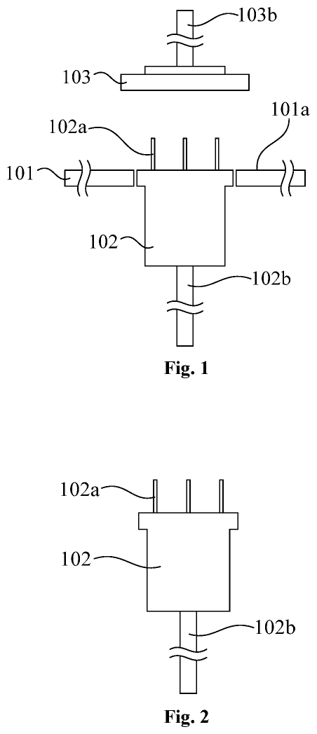

Please refer to FIG. 1 to FIG. 11. It should be noted that the drawings provided in the present embodiment illustrate the basic idea of the present invention only in a schematic manner. Although the drawings only show the components related to the present invention, rather than being drawn according to the number, shape and size of the components in actual implementation. The form, number and proportion of each component in actual implementation can be changed at will, and the layout of components may also be more complicated.

### Embodiment 1

Please refer to FIGS. 1 to 5 and FIGS. 7 to 9, the present embodiment discloses a die pickup device, including:

a carrier table 101, including a horizontal table surface 101a configured to place a die 200;

a pushing element 102 arranged in the carrier table 101, which includes ejector pins 102a switchable between an extended state and a retracted state in a direction vertical to the horizontal table surface 101a, wherein each of the ejector pins is configured to be at the same height in the extended state, wherein when the ejector pins 102a are in the extended state, a top of each of the ejector pins is higher than the horizontal table surface and is able to stay locked at a plurality of height positions; and

a vacuum fixture 103 configured to clamp the die 200 from the carrier table 101, which is arranged above the carrier table 101.

As shown in FIG. 1 which is a schematic diagram of a partial front view of a die pickup device provided in the embodiment. The die pickup device includes a carrier table 101. FIG. 1 shows part of the structure of the carrier table 101 to be in contact with the die 200, and the upper surface of the carrier table 101 is a horizontal table surface 101a. FIG. 1 further shows a pushing element 102 arranged in the carrier table 101, and a vacuum fixture 103 arranged above the carrier table 101.

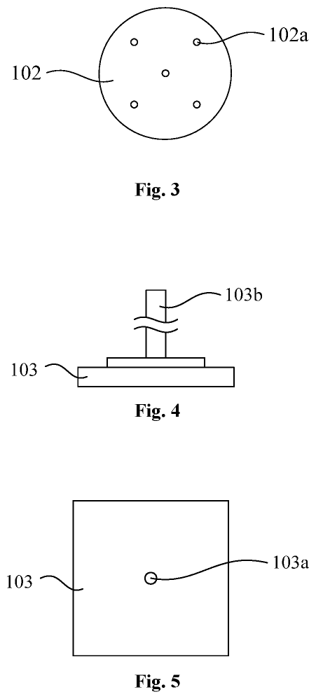

FIG. 2 shows a schematic diagram of a front view of the pushing element 102, and FIG. 3 is a top view thereof. It can be seen in FIG. 3 that, a plurality of the ejector pins 102a are available on the circular table surface. The plurality of the ejector pins 102a are distributed in a concentric array, symmetric to the circular center. The distance from each of the ejector pins 102a in the outermost circle of the concentric array to its closest edge of the circular table surface is one third of the radius of the circular table surface. As one example, five of the ejector pins 102a are available on the circular table surface, one of the ejector pins 102a is arranged in a center of the circular table surface, and remaining four of the ejector pins 102a are evenly distributed in the concentric array around the center ejector pin. It should be noted that the arrangement manner of the ejector pins 102a is not limited to the arrangement manner shown in FIG. 3, and the number and geometric pattern of the ejector pins 102a can be adjusted according to the size of the die 200.

As an example, the dimension of the die 200 is greater than 25×25 mm², the upper surface of the pushing element 102 is exposed to the surface of the horizontal table surface 101a of the carrier table 101, and the upper surface of the pushing element 102 is a circular table surface with a diameter greater than 45 mm. For a large-scale chip die, the dimension is generally greater than 25×25 mm², e.g., 30×26 mm², compared with the dimension of the existing conventional dies, such as 12×8 mm², the dies of large-scale chips are difficult to be firmly placed on the conventional die carrier table. By arranging a circular table surface with a diameter of greater than 45 mm, the dies of large-scale chips can be placed steadily on the circular table surface, such that the die pickup process is more stable. Optionally, the die 200 can be a flip-chip die prepared from wafer-level packaging in which metal pads and solder balls are already formed on the surface.

FIG. 4 is a schematic diagram of the vacuum fixture 103, and FIG. 5 is a bottom view of the vacuum fixture 103.

As an example, as shown in FIG. 5, the vacuum fixture 103 includes a vacuum nozzle 103a and a fixed structure 103b arranged above the vacuum nozzle 103a, the dimension of the fixed structure 103b is greater than 20×20 mm². It can be seen in FIG. 4 and FIG. 5 that, the fixed structure 103b on the vacuum fixture 103 is a vacuum pipeline 103b which is connected to a vacuum pump (not shown) to provide negative vacuum pressure to the vacuum nozzle 103a. As shown in FIG. 5, the vacuum fixture 103 is arranged at the bottom of the fixed structure 103b. When picking up the die 200, the vacuum nozzle 103a contacts the die 200 through the fixed structure 103b and locks the die 200 by vacuum suction. It should be noted that, multiple vacuum nozzles 103a may also be available, and these vacuum nozzles 103a may be arranged in an evenly distributed pattern on the fixed structure 103b to firmly grab the die 200.

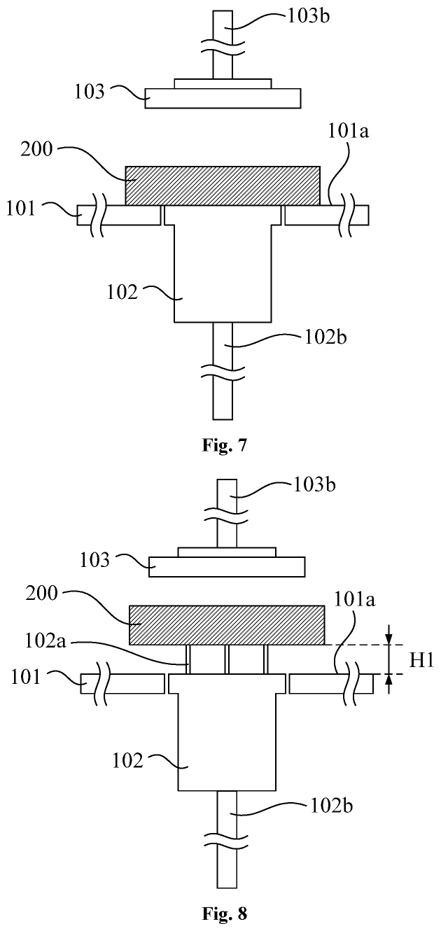

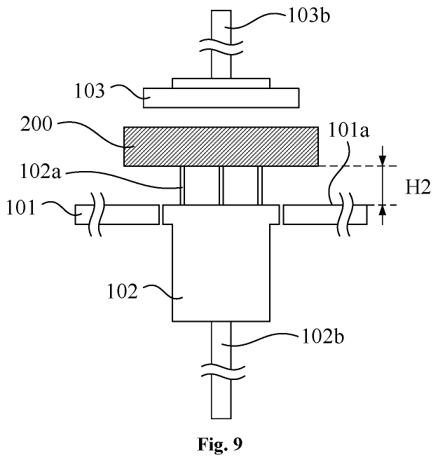

FIG. 7 is a schematic diagram showing that the die 200 is placed on the carrier table 101 when the ejector pins 102a of FIG. 1 are switched to a retracted state. As shown in FIGS. 8 and 9, each of the ejector pins 102a is configured to be at the same height in the extended state, wherein when the ejector pins are in the extended state, a top of each of the ejector pins is higher than the horizontal table surface and is able to stay locked at a plurality of height positions. For example, at the first height H1 or the second height H2; the second height H2 is greater than the first height H1, and the difference between the first height H1 and the second height H2 is less than the first height H1. In FIG. 8, the top of each of the ejector pins 102a is at the first height H1, and in FIG. 9, the top of each of the ejector pins 102a is at the second height H2.

As an example, the pushing element 102 further includes a drive unit configured to drive the ejector pins 102a to extend or retract in a direction vertical to the horizontal table surface 101a. Optionally, the pushing element 102 is provided with an axial rod structure 102b which is configured to support the pushing element 102 and to connect the ejector pins 102a and the drive unit (not shown), such that the drive unit can drive the ejector pins 102a to extend or retract via the rod structure 102b. At either the first height H1 or the second height H2, the ejector pins 102a are kept fixed, such that the die 200 supported by the ejector pins 102a can be temporarily maintained in the corresponding fixed position. Optionally, the drive unit includes a stepper motor, which is in transmission connection to the ejector pins 102a by means of the rod structure 102b, to drive the ejector pins 102a to extend or retract.

As an example, the pushing element 102 further includes a timing unit configured to control the durations during which the ejector pins 102a remain at a fixed position at the first height and the second height. Optionally, the timing unit is connected with the drive unit and controls the drive unit to move the ejector pins 102a after a desired fixed duration at either the first height H1 or the second height H2. The range of the retention duration for each of the fixed positions can be 0.05-1.0 second, for example, 0.1 second.

As an example, the die pickup device further includes:

a control unit which connects the pushing element 102 and the vacuum fixture 103 and which is configured to control the pushing element 102 to push the die 200, to control the vacuum fixture 103 to pick up the die 200, and to determine whether the vacuum fixture 103 has picked up the die 200.

Optionally, the control unit is connected to the drive unit and the timing unit, to control the drive unit and the timing unit to drive the ejector pins 102a to extend or retract, and to maintain a fixed duration at the first height and the second height. The control unit is further connected to the vacuum fixture 103, to control the vacuum fixture 103 to pick up the die 200 and to determine whether the vacuum fixture 103 has picked up the die 200. For example, whether the vacuum fixture 103 has picked up the die 200 is determined by determining the vacuuming state inside the vacuum fixture 103.

As an example, the die pickup process in the present embodiment is performed after a wafer is cut into dies, and these dies are placed on a moving carrier belt (not shown in the figure) and moved on to the horizontal table surface 101a by the carrier belt. By means of movement of the carrier belt in the horizontal direction, the dies to be picked up are transferred sequentially in the moving direction the carrier belt to the top of the pushing element 102, and each die is lifted up by the pushing element 102 and is picked up by the vacuum fixture 103. The vacuum fixture 103 picks up the dies one by one and transfers them to the next packaging processing site.

### Embodiment 2

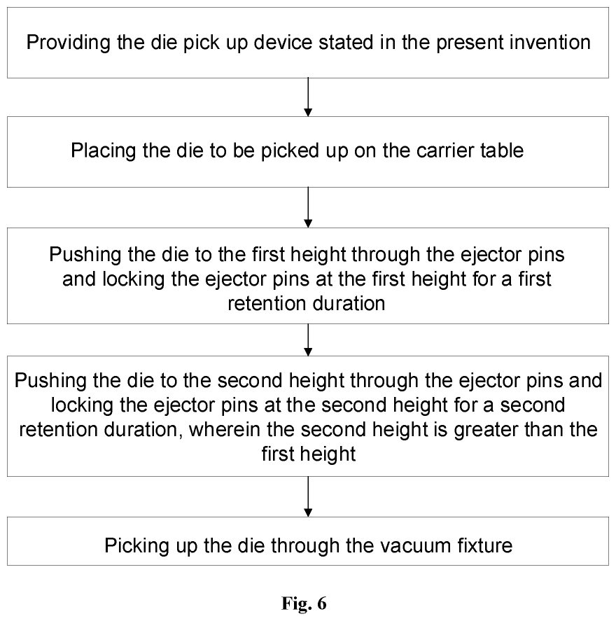

As shown in FIG. 6 to FIG. 11, the present embodiment provides a die pickup method, including the following steps:

1) providing the die pickup device stated in embodiment 1;

2) placing the die 200 to be picked up on the carrier table 101;

3) pushing the die 200 to a first height through the ejector pins 102a, herein the die 200 is configured to be at the first height for a first retention duration;

4) pushing the die 200 to a second height through the ejector pins 102a and staying for a second retention duration, wherein the second height is greater than the first height; and

5) picking up the die 200 through the vacuum fixture 103.

In step 1), please refer to step S1 of FIG. 6 and FIGS. 1 to 5, a die pickup device as described in embodiment 1 is provided. As shown in FIGS. 1 to 5, the die pickup method of the present embodiment is built to use the die pickup device as described in embodiment 1. In other embodiments of the present invention, the die pickup method may also apply to a die pickup device having a similar structure as the die pickup device described in embodiment 1.

In step 2), please refer to step S2 of FIG. 6 and FIG. 7, the die 200 to be picked up are placed on the carrier table 101. As shown in FIG. 7, when the die 200 is placed on the carrier table 101, the ejector pins 102a are in a retracted state and the bottom surface of die 200 is flush with the surface of the horizontal table surface 101a, thereby ensuring that the die 200 is placed on the carrier table 101 in a stable position.

In step 3), please refer to step S3 of FIG. 6 and FIG. 8, the die 200 is pushed to a first height H1 by the ejector pins 102a and maintained for a first retention duration. As shown in FIG. 8, the ejector pins 102a are controlled by the drive unit to push the die 200 to a first height H1. Optionally, the die is maintained at the first height H1 for a first retention duration, and the first retention duration is 0.05 to 1 second, for example 0.1 second.

In step 4), please refer to step S4 of FIG. 6 and FIG. 9, the die 200 is pushed to a second height H2 by the ejector pins 102a and maintained for a second retention duration, and the second height H2 is greater than the first height H1. As shown in FIG. 9, the ejector pins 102a are controlled by the drive unit to continuously push the die 200 to a second height H2. Optionally, the die 200 is maintained at the second height H2 for a second retention duration, and the second retention duration is 0.05 to 1 second, for example 0.1 second. In other embodiments of the present invention, the second retention duration and the first retention duration may also be set to be different.

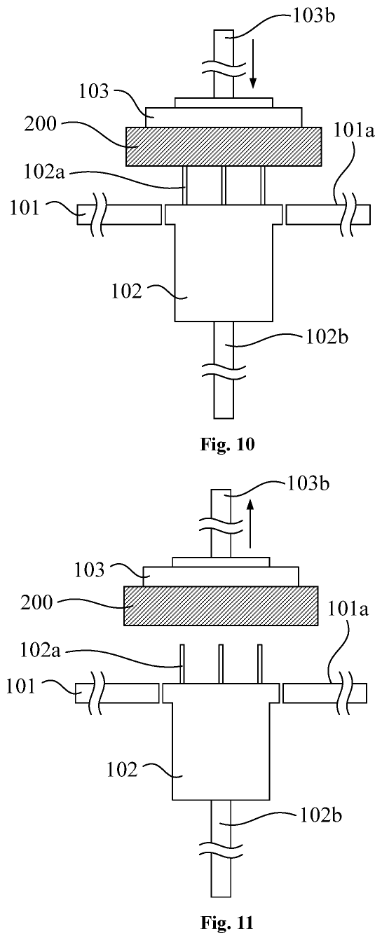

In step 5), please refer to step S5 of FIG. 6 and FIGS. 10 to 11, the die 200 are picked up by the vacuum fixture 103. In FIG. 10, the vacuum fixture 103 approaches the die 200 in the direction of the arrow in the figure and picks the die 200 up, and after the vacuum fixture 103 has grabbed the die 200, the vacuum fixture 103 picks up the die 200 to the next packaging process site for further processing.

As an example, the method further includes following steps after step 5):

step 6) determining whether the vacuum fixture 103 has picked up the die 200;

step 7) when confirming that the vacuum fixture 103 has picked up the die 200, the vacuum fixture 103 clamps and transfers the die 200 to the next processing stage; and

when determining that the vacuum fixture 103 has not picked up the die 200, the ejector pins 102a return to the retracted state and perform step 3) to step 7) again.

The dies of large-scale chips have larger dimension and more demanding quality which makes the pickup process more difficult, for example, if the die 200 moves before the vacuum fixture 103 has firmly grabbed the die 200, it may result in an abnormality of dropping or even breaking of the die. The above situation can be avoided by first determining whether the vacuum fixture 103 has picked up the die 200 before the die is moved. Whether the vacuum fixture 103 has picked up the die 200 or not can be determined through a control unit. For example, whether the vacuum fixture 103 has picked up the die 200 or not can be determined through knowing what the vacuum state is inside the vacuum fixture 103. If it is found that the die 200 is not picked up, then step 3) to step 7) may be repeated until the vacuum fixture 103 picks up the die 200.

In summary, the present invention provides a die pickup device and method, the die pickup device includes: a carrier table, including a horizontal table surface configured to place a die; a pushing element arranged in the carrier table, which includes ejector pins that can be switched between in an extended state and in a retracted state along a direction perpendicular to the horizontal table surface, wherein when the ejector pins are in the extended state, the tops of the ejector pins are higher than the horizontal table surface. Each of the ejector pins is configured to be at the same height in the extended state, when the ejector pins are in the extended state, a top of each of the ejector pins is higher than the horizontal table surface and is able to stay locked at a plurality of height positions. The die pickup device further includes a vacuum fixture configured to pick up dies from the carrier table. In the present invention, a die pickup device for large-scale chips and how to operate it are optimized and adjusted, thereby ensuring that the process of picking up dies of large-scale chips have a high success rate. Through the multiple height lifting ejector pin design and ability to adjust the lifting height and retention duration of the ejector pins, the vacuum fixture can successfully pick up large-scale chip dies.

The above embodiments are merely illustrative of the principles of the present invention and its effects, and are not intended to limit the present invention. Any of those skilled in the art may modify or change the above embodiments without violating the spirit and scope of the present invention. Therefore, all the equivalent modifications or alterations made by those with ordinary knowledge in the art without departing from the spirit and technical ideas revealed by the present invention shall still fall within the claims of the present invention.

1. A die pickup device, comprising:
a carrier table, comprising a horizontal table surface above a pushing element, wherein the horizontal table surface is configured to place a die;
ejector pins configured to mount on the horizontal table surface, wherein the ejector pins are configured to switch between an extended state and a retracted state in a direction perpendicular to the horizontal table surface, wherein when the ejector pins are in the extended state, each of the ejector pins is configured to be at a same height as other ejector pins in the extended state, wherein a top of each of the ejector pins is higher than the horizontal table surface, and is able to stay locked at different height positions; and
a vacuum fixture configured to grab the die from the horizontal table surface of the carrier table.

2. The die pickup device according to claim 1, wherein the different height positions of the ejector pins able to be locked at comprise at least a first height and a second height; wherein the second height is greater than the first height, and wherein the difference between the first height and the second height is smaller than the first height.

3. The die pickup device according to claim 1, wherein the pushing element further comprises a drive unit configured to drive the ejector pins to extend or retract in a direction perpendicular to the horizontal table surface.

4. The die pickup device according to claim 2, wherein the pushing element further comprises a timing unit configured to control the duration for which the ejector pins remaining locked at the first height and the second height.

5. The die pickup device according to claim 1, wherein the die is rectangular, having an area greater than 25×25 mm², wherein an upper surface of the pushing element is exposed out of the horizontal table surface of the carrier table, wherein the upper surface of the pushing element is a circular table surface with a diameter greater than 45 mm.

6. The die pickup device according to claim 5, wherein the ejector pins are distributed in a concentric array on the circular table surface of the pushing element, and wherein a distance from each of outermost ejector pins in the concentric array to a closest edge of the circular table surface is one third of a radius of the circular table surface.

7. The die pickup device according to claim 6, wherein a number of the ejector pins is five, wherein one of the ejector pins is arranged in a center of the circular table surface, and remaining four of the ejector pins are evenly place around the center at a same distance from said ejector pin at the center.

8. The die pickup device according to claim 5, wherein the vacuum fixture comprises a vacuum nozzle and a structure arranged around the vacuum nozzle, wherein a size of the structure is greater than 20×20 mm².

9. The die pickup device according to claim 1, further comprising:
a control unit which connects to the pushing element and the vacuum fixture, wherein the control unit is configured to control the pushing element to push the die, to control the vacuum fixture to pick up the die, and to determine whether the vacuum fixture has picked up the die.

10. A die pickup method, comprising the following steps:
1) providing the die pickup device according to claim 2;
2) placing the die to be picked up on the carrier table;
3) pushing the die to the first height through the ejector pins and locking the ejector pins at the first height for a first retention duration;
4) pushing the die to the second height through the ejector pins and locking the ejector pins at the second height for a second retention duration, wherein the second height is greater than the first height; and
5) picking up the die through the vacuum fixture.

11. The die pickup method according to claim 10, wherein the first retention duration and the second retention duration are both 0.05 to 1.0 second.

12. The die pickup method according to claim 10, further comprising following steps after step 5):
step 6) determining whether the vacuum fixture has picked up the die;
step 7) when confirming that the vacuum fixture has picked up the die, grabbing and transferring the die with the vacuum fixture; and when determining that the vacuum fixture has not picked up the die, returning the ejector pins to the retracted state and performing step 3) to step 7) again.
